(19) United States
(12) Patent Application Publication
(10) Pub. No.: US 2024/0395929 A1
(43) Pub. Date: Nov. 28, 2024

(54) SEMICONDUCTOR DEVICE AND METHOD OF FABRICATING THE SAME

(71) Applicant: United Microelectronics Corp., Hsinchu (TW)

(72) Inventors: Chen-Yuan Lin, Hsinchu City (TW); Yu-Cheng Lo, Hsinchu County (TW); Tzu-Yun Chang, Hsinchu County (TW)

(73) Assignee: United Microelectronics Corp., Hsinchu (TW)

(21) Appl. No.: 18/337,396

(22) Filed: Jun. 19, 2023

(30) Foreign Application Priority Data
May 26, 2023 (TW) 112119698

(51) Int. Cl. H01L 29/78; H01L 29/06; H01L 29/40; H01L 29/423; H01L 29/66

(52) U.S. Cl. CPC H01L 29/7816; H01L 29/0653; H01L 29/401; H01L 29/402; H01L 29/42356; H01L 29/42364; H01L 29/66689; H01L 29/665

(57) ABSTRACT

A semiconductor device includes a gate structure, a first doped region, a second doped region, an isolation structure, an insulating layer and a field plate. The gate structure is located on a substrate. The first doped region and the second doped region are located at two sides of the gate structure. The isolation structure is located in the substrate between the first doped region and the second doped region, and is separated from the gate structure by a non-zero distance. The insulating layer extends continuously from a portion of a top surface of the gate structure to a portion of a top surface of the isolation structure. The field plate is located on the insulating layer and has the same potential as the gate structure.

### CROSS-REFERENCE TO RELATED APPLICATION

This application claims the priority benefit of Taiwan application serial no. 112119698, filed on May 26, 2023. The entirety of the above-mentioned patent application is hereby incorporated by reference herein and made a portion of this specification.

### BACKGROUND

### Technical Field

The embodiments of the present disclosure relate to an integrated circuit and a method of fabricating the same, and particularly to a semiconductor device and a method of fabricating the same.

### Description of Related Art

Transistors are indispensable electronic devices in integrated circuits. Depending on different applied voltages, various transistors with different voltages are provided. High-voltage (HV) transistors, such as laterally diffused metal-oxide-semiconductor (LDMOS) field-effect transistors, can be used as high-voltage switching regulators and high-voltage switches in power management integrated circuits (ICs). In order to handle the high voltages involved in these and other high voltage applications, it is desirable to have a high voltage transistor with high breakdown voltage and low on-resistance.

### SUMMARY

The disclosure provides a semiconductor device and a manufacturing method thereof, so as to reduce the influence of the hot carrier effect and therefore improve the breakdown voltage and the performance of the semiconductor device.

In an embodiment of the present disclosure, a semiconductor device includes a gate structure, a first doped region, a second doped region, an isolation structure, an insulating layer and a field plate. The gate structure is located on the substrate. The first doped region and the second doped region are located at two sides of the gate structure. The isolation structure is located in the substrate between the first doped region and the second doped region, and is separated from the gate structure by a non-zero distance. The insulating layer extends continuously from a portion of a top surface of the gate structure to a portion of a top surface of the isolation structure. The field plate is located on the insulating layer and has the same potential as the gate structure.

In an embodiment of the present disclosure, a method of fabricating a semiconductor device includes the following steps. An isolation structure is formed in the substrate. A gate structure is formed on the substrate. A first doped region and a second doped region are formed at two sides of the gate structure. An isolation structure is formed in the substrate between the first doped region and the second doped region, and is separated from the gate structure by a non-zero distance. An insulating layer is formed extending continuously from a portion of a top surface of the gate structure to a portion of a top surface of the isolation structure. A field plate is formed on the insulating layer. The field plate is electrically connected to the gate structure, so the field plate and the gate structure are equipotential.

Based on the above, the semiconductor device and the manufacturing method thereof according to the embodiments of the present disclosure can reduce the influence of the hot carrier effect and therefore improve the breakdown voltage and the performance of the semiconductor device.

### BRIEF DESCRIPTION OF THE DRAWINGS

FIG. 1A to FIG. 1H are cross-sectional views of a method of fabricating a semiconductor device according to an embodiment of the present disclosure.

### DESCRIPTION OF THE EMBODIMENTS

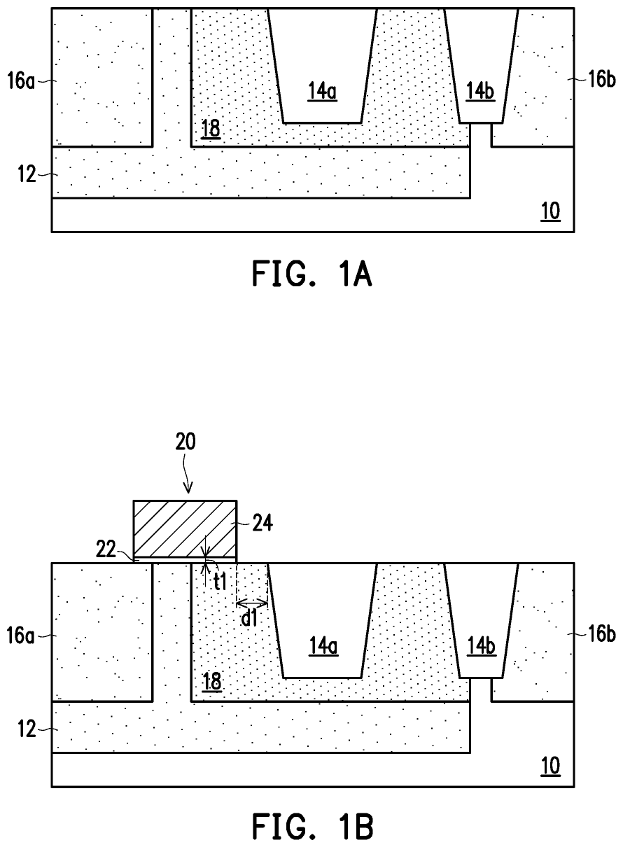

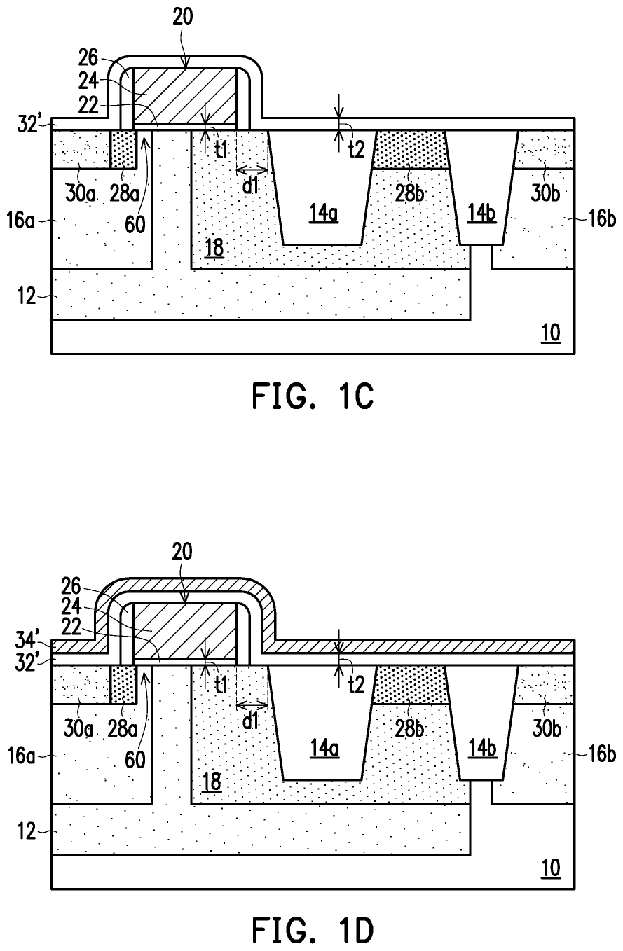

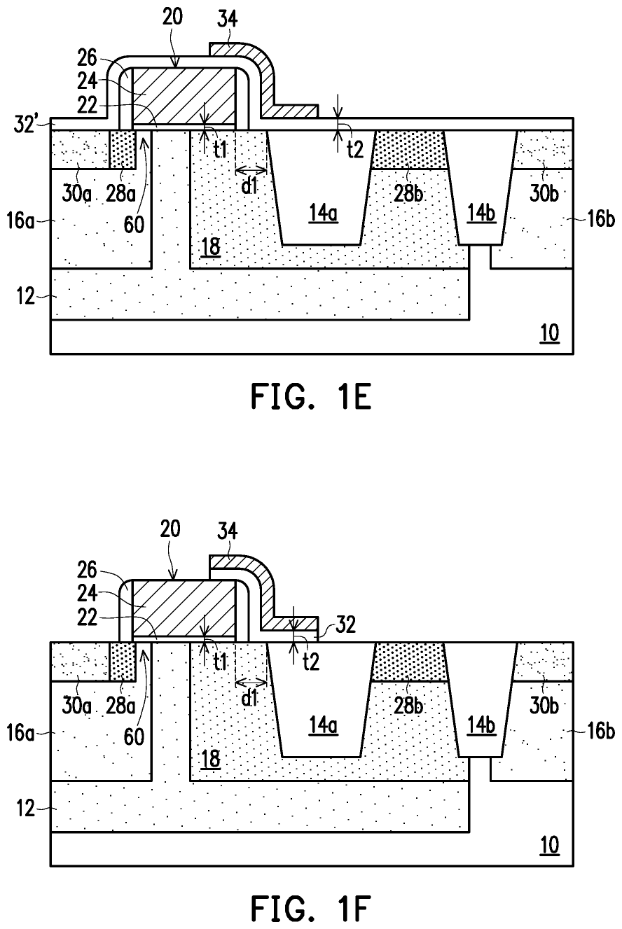

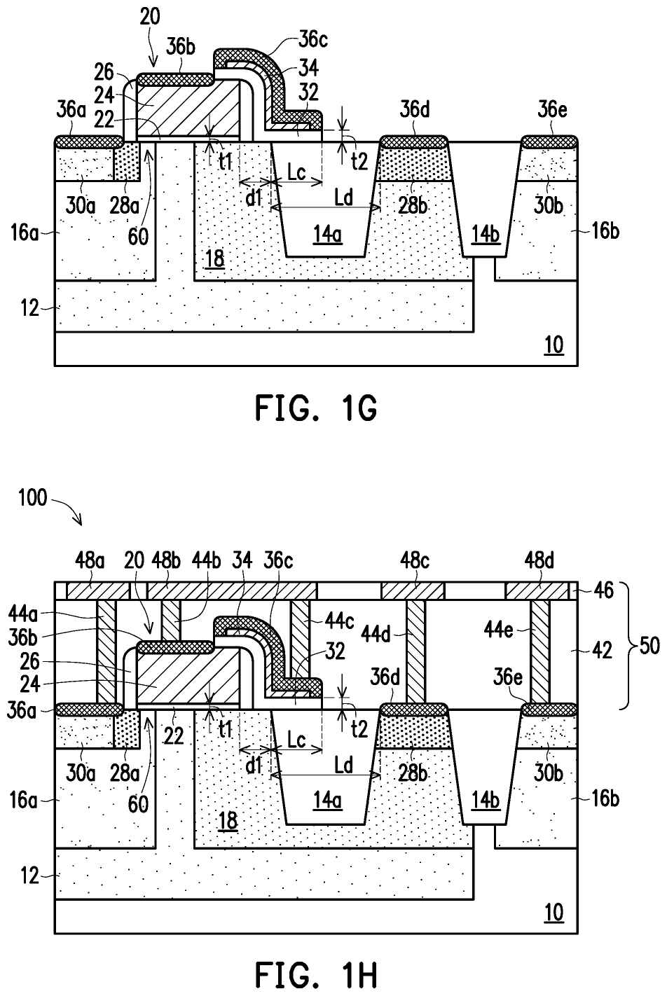

FIG. 1A to FIG. 1H are cross-sectional views of a method of fabricating a semiconductor device according to an embodiment of the present disclosure.

Referring to FIG. 1H, the semiconductor device 100 of the embodiment of the present disclosure may be an LDNMOS transistor. The semiconductor device 100 includes a gate structure 20, doped regions 28a and 28b, an isolation structure 14a, an insulating layer 32 and a field plate 34. The gate structure 20 is located on the substrate 10. The doped region 28a and 28b are located at two sides of gate structure 20. The isolation structure 14a is located in the substrate 10 between the doped regions 28a and 28b, and is separated from the gate structure 20 by a non-zero distance d1. The insulating layer 32 extends continuously from a portion of the top surface of the gate structure 20 to a portion of the top surface of the isolation structure 14a. The field plate 34 is located on the insulating layer 32 and has the same potential as the gate structure 20.

In the embodiment of the present disclosure, the gate structure 20 is separated from the isolation structure 14a, and an insulating layer 32 is located between the gate structure 20 and the isolation structure 14a. The thickness of the insulating layer 32 is greater than the thickness of the gate dielectric layer 22 of the gate structure 20. Therefore, the electric field can be released, the ionization impact on the top surface at the corner of the isolation structure 14a can be reduced, and the breakdown voltage and the performance of the device can be accordingly improved.

In the embodiment of the present disclosure, the insulating layer 32 covers a portion of the top surface of the gate structure 20 and the sidewall of the spacer 26, a portion of the top surface of the well region 18 between the gate structure 20 and the isolation structure 14a, and a portion of the top surface of the isolation structure 14a. The width Lc of the isolation structure 14a covered by the insulating layer 32 is about 30% to 80% of the top width Ld of the isolation structure 14a.

The insulating layer 32 may include silicon oxide. The insulating layer 32 can be integrated with the existing manufacturing process. For example, the insulating layer 32 can be a salicide block (SAB) layer in a self-aligned silicide process. Therefore, it can be integrated with the existing manufacturing process without an additional process step.

Referring to FIG. 1H, in the embodiment of the present disclosure, the electric field can be dispersed by disposing the field plate 34. The field plate 34 overlies the insulating layer 32. The field plate 34 includes polysilicon. The field plate 34 can be electrically connected to the gate conductive layer 24 of the gate structure 20 through an interconnect structure 50, so that the field plate 34 and the gate conductive layer 24 are equipotential.

FIG. 1A to FIG. 1H are cross-sectional views of a method of fabricating a semiconductor device according to an embodiment of the present disclosure.

Referring to FIG. 1A, isolation structures 14a and 14b are formed in substrate 10. The substrate 10 may include a semiconductor substrate or a semiconductor compound substrate, such as a silicon substrate or a silicon germanium substrate. The substrate 10 may have a dopant of a first conductivity type. The dopant of the first conductivity type can be a P-type dopant, such as boron or boron trifluoride. The dopant of the first conductivity type can be an N-type dopant, such as phosphorus or arsenic.

Thereafter, a deep well region 12, well regions 16a, 18, 16b and isolation structures 14a and 14b are formed in substrate 10. The well region 16a is located in deep well region 12. The well region 16b is located in the substrate 10 outside the deep well region 12. The well region 18 is located within the deep well region 12 in the substrate 10, and the sidewall of the well region 18 is aligned with (as shown in FIG. 1A) or not exceeding (not shown) the sidewall of the deep well region 12. In addition, the well region 18 is located between the well region 16a and the well region 16b, and is separated from the well region 16a and the well region 16b by a non-zero distance. The isolation structure 14a is located in well region 18. The isolation structure 14b is located between the well region 18 and the well region 16b. The isolation structures 14a and 14b respectively define multiple active areas.

Each of the deep well region 12 and the well region 18 may have a dopant of a second conductivity type. The dopant of the second conductivity type is different from the dopant of the first conductivity type. The dopant of the second conductivity type can be an N-type dopant, such as phosphorus or arsenic. The dopant of the second conductivity type a P-type dopant, such as boron or boron trifluoride. Each of the well regions 16a, 16b may have a dopant of the first conductivity type. The dopant of the first conductivity type can be a P-type dopant, such as boron or boron trifluoride. The dopant of the first conductivity type can be an N-type dopant, such as phosphorus or arsenic. The deep well region 12, the well regions 16a, 18, 16b can be formed by ion implantation processes. The isolation structures 14a and 14b may include silicon oxide, silicon nitride or a combination thereof. The isolation structures 14a and 14b may be shallow trench isolation structures. In other words, the isolation structures 14a and 14b can be formed by a shallow trench isolation method.

In some embodiments, a deep well region 12 may be first formed in substrate 10. Thereafter, isolation structures 14a and 14b are formed in the substrate 10. Afterwards, well regions 16a, 16b are formed in the substrate 10. A well region 18 is then formed. However, the embodiments of the present disclosure are not limited thereto.

Referring to FIG. 1B, a gate structure 20 is formed on the substrate 10. The gate structure 20 includes a gate dielectric layer 22 and a gate conductive layer 24. The method of forming the gate structure 20 includes forming a gate dielectric material and a gate conductive material on the substrate 10. Then, lithography and etching processes are performed to pattern the gate dielectric material and the gate conductive material, so as to form the gate dielectric layer 22 and the gate conductive layer 24. The gate dielectric layer 22 may include silicon oxide, silicon nitride or a high dielectric constant material. The gate conductive layer 24 may include doped polysilicon.

The gate structure 20 covers a portion of the well region 16a, a portion of the deep well region 12 and a portion of the well region 18. The gate structure 20 does not extend to cover the isolation structure 14a. The gate structure 20 exposes a portion of the surface of the well region 18 and the entire surface of the isolation structure 14a. There is a non-zero distance d1 between the gate dielectric layer 22 of the gate structure 20 and the isolation structure 14a. The distance d1 may be about 0.1 μm to 1 μm, for example.

Referring to FIG. 1C, spacers 26 are formed at two sides of the gate structure 20. The material of the spacers 26 may include silicon oxide, silicon nitride or a combination thereof. The spacers 26 can have a single-layer or multi-layer structure. In some embodiments, the spacers 26 do not extend to cover the isolation structure 14a, and expose a portion of the well region 18.

Thereafter, doped regions 28a, 28b and doped regions 30a, 30b are formed in the substrate 10 at two sides of the gate structure 20 and the isolation structure 14a. The doped regions 28a and 28b are located in the well region 16a and the well region 18, respectively. The doped regions 30a and 30b are located in the well regions 16a and 16b, respectively. There is a channel region 60 below the gate structure 20. The channel region 60 is located in the well region 16a between the doped region 28a and the deep well region 12. Each of the doped regions 28a and 28b may have a dopant of the second conductivity type. The dopant of the second conductivity type is different from the dopant of the first conductivity type. The dopant of the second conductivity type can be an N-type dopant, such as phosphorus or arsenic. The dopant of the second conductivity type can be a P-type dopant, such as boron or boron trifluoride. Each of the doped regions 30a, 30b may have a dopant of the first conductivity type. The dopant of the first conductivity type can be a P-type dopant, such as boron or boron trifluoride. The dopant of the first conductivity type can be an N-type dopant, such as phosphorus or arsenic.

Referring to FIG. 1C, an insulating material 32′ is formed over the substrate 10. The insulating material 32′ covers the doped regions 30a, 28a, the spacer 26, the top surface of the gate structure 20, the well region 18 between the gate structure 20 and the isolation structure 14a, the isolation structure 14a, the doped region 28b, the isolation structure 14b and the doped region 30b. In this embodiment, the insulating material 32′ may be a salicide block (SAB) layer. The material of the salicide block layer may include silicon oxide, for example. In this embodiment, the thickness t2 of the insulating material 32′ is greater than the thickness t1 of the gate dielectric layer 22. The ratio of the thickness t2 of the insulating material 32′ to the thickness t1 of the gate dielectric layer 22 may be from about 2 to 5, for example.

Referring to FIG. 1D, a field plate material 34′ is formed over the substrate 10 to cover the insulating material 32′. The field plate material 34′ may include semiconductor such as undoped polysilicon.

Referring to FIG. 1E, lithography and etching processes are performed to pattern the field plate material 34 to form a field plate 34. The field plate 34 covers a portion of the insulating material 32′. The disposition of the field plate 34 can disperse the electric field.

Referring to FIG. 1F, lithography and etching processes are performed to remove a portion of the insulating material 32′, so as to form an insulating layer 32. The insulating layer 32 extends from a portion of the top surface of the gate structure 20, along the sidewall of the spacer 26, to a portion of the top surface of the well region 18 and a portion of the isolation structure 14a, while exposing the doped regions 30a, 28a, another portion of the top surface of the gate conductive layer 24 of the gate structure 20, and the doped regions 28b, 30b. In some embodiments, the ratio of the width Lc of the isolation structure 14a covered by the insulating layer 32 to the top width Ld of the isolation structure 14a may be from about 30% to 80%, for example. In some embodiments, the width Lc of the isolation structure 14a covered by the insulating layer 32 is greater than ½ of the top width Ld of the isolation structure 14a.

Referring to FIG. 1G, metal silicide layers 36a, 36b, 36c, 36d, and 36e are formed on the doped regions 30a, 28a, the gate conductive layer 24 of the gate structure 20, the field plate 34, the doped regions 28b, 30b, respectively. The metal silicide layers 36a, 36b, 36c, 36d and 36e may be formed by a self-aligned metal silicide process. First, a metal layer is formed on the substrate 10. The metal layer may include nickel, for example. Next, a thermal annealing process is performed to make the metal layer react with silicon in the doped regions 30a, 28a, the gate conductive layer 24 of the gate structure 20, the field plate 34, and the doped regions 28b, 30b, so as to form the metal silicide layers 36a, 36b, 36c, 36d and 36e. Afterwards, the unreacted metal layer is removed, so that the metal silicide layers 36a, 36b, 36c, 36d, and 36e remain on the doped regions 30a, 28a, the gate conductive layer 24 of the gate structure 20, the field plate 34, and the doped regions 28b, 30b.

Referring to FIG. 1H, a metallization process is performed to form an interconnect structure 50 on the substrate 10. A dielectric layer 42 is formed on the substrate 10. The dielectric layer 42 may include silicon oxide or undoped silica glass (USG). The dielectric layer 42 can be planarized through a planarization process, such as a chemical mechanical polishing process.

Thereafter, contacts 44a, 44b, 44c, 44d, and 44e are formed in the dielectric layer 42. The contacts 44a, 44b, 44c, 44d, 44e can be formed according to the method described below. For example, multiple contact openings are formed in the dielectric layer 42 by lithography and etching processes, and a conductive material is then formed in the multiple contact openings and on the dielectric layer 42. The conductive material may include tungsten, for example. A barrier material (e.g., tantalum, tantalum nitride, titanium, titanium nitride, or a combination thereof) may be formed prior to the formation of the conductive material. Afterwards, the barrier material and the conductive material on the dielectric layer 42 are removed by a chemical mechanical polishing process or an etch-back process.

Afterwards, conductive lines 48a, 48b, 48c and 48d are formed on the dielectric layer 42. The conductive lines 48a, 48b, 48c and 48d are formed by forming a conductive material on the dielectric layer 42, and then patterning the conductive material through lithography and etching processes, for example. After that, a dielectric layer 46 is formed on the dielectric layer 42 and the conductive lines 48a, 48b, 48c, and 48d. The material of the dielectric layer 46 may include silicon oxide or undoped silicon glass. The method of forming the dielectric layer 46 may include forming a dielectric material on the dielectric layer 42 and the conductive lines 48a, 48b, 48c, and 48d, and then performing a chemical mechanical polishing process or an etching back process to remove the dielectric material on the conductive lines 48a, 48b, 48c, and 48d.

The dielectric layers 42, 46, the conductive lines 48a, 48b, 48c, and 48d in the above-mentioned interconnect structure 50 can also be formed by another method, such as a single damascene process. The single damascene process includes forming a dielectric layer 46, forming a trench in the dielectric layer 46 through lithography and etching processes, forming a conductive material on the dielectric layer 46 and in the trench, and performing a chemical mechanical polishing process or an etching back process to removes the excess conductive material on the dielectric layer 46 and therefore form the conductive lines 48a, 48b, 48c and 48d. In other embodiments, the conductive lines 48a, 48b, 48c, and 48d and the contacts 44a, 44b, 44c, 44d, and 44e may be formed by a dual damascene process.

The conductive line 48a is electrically connected to the doped regions 30a and 28a through the contact 44a and the metal silicide layer 36a. The conductive line 48b is electrically connected to the gate conductive layer 24 through the contact 44b and the metal silicide layer 36b. The conductive line 48b is further electrically connected to the field plate 34 through the contact 44c and the metal silicide layer 36c. That is, the gate conductive layer 24 and the field plate 34 are electrically connected to each other and have the same potential. The conductive line 48c is electrically connected to the doped region 28b through the contact 44d and the metal silicide layer 36d. The conductive line 48d is electrically connected to the doped region 30b through the contact 44e and the metal silicide layer 36e.

In this embodiment, the gate conductive layer 24 and the field plate 34 are electrically connected to each other through the conductive line 48b of a first metal layer. However, the embodiment of the present disclosure is not limited thereto. In other embodiments, the gate conductive layer 24 and the field plate 34 can be electrically connected to each other through a conductive line of a second metal layer, a third metal layer or a higher-level metal layer, as long as the gate conductive layer 24 and the field plate 34 can be equipotential.

### Example 1

The thickness of gate dielectric layer 22 is about 120 angstroms, and the thickness of insulating layer (e.g., salicide block layer) 32 is about 300 angstroms. The width Ld of the isolation structure 14a is about 2.7 μm. The distance d1 between the gate dielectric layer 24 of the gate structure 20 and the isolation structure 14a is about 0.27 μm.

### Example 2

The thickness of gate dielectric layer 22 is about 120 angstroms, and the thickness of insulating layer (e.g., salicide block layer) 32 is 300 angstroms. The width Ld of the isolation structure 14a is about 2 μm. The distance d1 between the gate dielectric layer 24 of the gate structure 20 and the isolation structure 14a is about 0.27 μm.

### Comparative Example 1

The thickness of gate dielectric layer 22 is about 120 angstroms, and the thickness of insulating layer (e.g., salicide block layer) 32 is 300 angstroms. The width Ld of the isolation structure 14a is about 2.7 μm. The gate dielectric layer 24 of the gate structure 20 extends to cover the isolation structure 14a, and the distance d1 is about zero.

TABLE 1

| | Isolation | | Turn-on | |
|---|---|---|---|---|
| | structure | Breakdown | resistance | Performance |
| | width Ld | voltage BV | Rdson | FOM |
| | (μm) | (V) | (mohm × mm²) | (BV/Rdson) |
| Comparative | 2.7 | 65.3 | 66.87 | 0.98 |
| Example 1 | | | | |
| Example 1 | 2.7 | 79.5 | 68.79 | 1.16 |
| Example 2 | 2 | 65.1 | 49.45 | 1.32 |

Table 1 shows the breakdown voltage BV, the turn-on resistance Rdson and the performance (i.e., the ratio of breakdown voltage BV to turn-on resistance Rdson) FOM of each of Example 1, Example 2 and Comparative Example 1. The results of Example 1 and Comparative Example 1 in Table 1 show that: under the same isolation structure width Ld, Example 1 and Comparative Example 1 have substantially the same turn-on resistance Rdson, but the breakdown voltage of Example 1 can be greatly improved. The performance FOM of Comparative Example 1 is 0.98, while the performance FOM of Example 1 can be increased to 1.16.

The results of Example 2 and Comparative Example 1 in Table 1 show that: under substantially the same breakdown voltage BV, the performance FOM of Comparative Example 1 having a larger isolation structure width Ld is 0.98, but the performance FOM of Example 2 having a smaller isolation structure width Ld can be increased to 1.32. The performance FOM can be increased by 34.8%.

In the method of the embodiments of the present disclosure, the electric field at the corner of the isolation structure can be greatly dispersed by separating a gate structure from an isolation structure, disposing an insulating layer (having a thickness greater than that of a gate dielectric layer of the gate structure) between the gate structure and the isolation structure, and disposing a field plate on the insulating layer. By such configuration, the influence of the hot carrier effect can be reduced, the breakdown voltage and the performance of the device can be greatly improved. On the other hand, with the method of the embodiment of the present disclosure, the performance of the device can be improved while shrinking the isolation structure. Therefore, the chip area occupied by the isolation structure can be reduced.

What is claimed is:

1. A semiconductor device, comprising:
a gate structure, located on a substrate;
a first doped region and a second doped region, located at two sides of the gate structure;
an isolation structure, located in the substrate between the first doped region and the second doped region, and separated from the gate structure by a non-zero distance;
an insulating layer, extending continuously from a portion of a top surface of the gate structure to a portion of a top surface of the isolation structure; and
a field plate, located on the insulating layer, wherein the field plate and the gate structure are equipotential.

2. The semiconductor device according to claim 1, wherein a thickness of the insulating layer is greater than a thickness of a gate dielectric layer of the gate structure.

3. The semiconductor device according to claim 1, wherein a width of the isolation structure covered by the insulating layer is greater than 30% to 80% of a top width of the isolation structure.

4. The semiconductor device according to claim 1, wherein the insulating layer is a salicide block layer.

5. The semiconductor device according to claim 4, wherein the salicide block layer comprises silicon oxide.

6. The semiconductor device according to claim 1, wherein the field plate comprises a semiconductor.

7. The semiconductor device according to claim 6, wherein the field plate comprises undoped polysilicon.

8. The semiconductor device according to claim 1, further comprising a plurality of metal silicide layers, located on a top surface of the first doped region, a top surface of the second doped region, a top surface of the field plate, and a top surface of a gate conductive layer of the gate structure uncovered by the insulating layer, respectively.

9. The semiconductor device according to claim 8, further comprising an interconnect structure electrically connected to the field plate and the gate conductive layer of the gate structure.

10. The semiconductor device according to claim 9, wherein the interconnect structure comprises:
a first contact, electrically connected to the field plate;
a second contact, electrically connected to the gate conductive layer of the gate structure; and
a conductive line, connected to the first contact and the second contact.

11. The semiconductor device according to claim 10, wherein the first contact is electrically connected to the field plate through one of the plurality of metal silicide layers, and the second contact is electrically connected to the gate conductive layer through another of the plurality of metal silicide layers.

12. A method of fabricating a semiconductor device, comprising:
forming an isolation structure in a substrate;
forming a gate structure on the substrate;
forming a first doped region and a second doped region at two sides of the gate structure, wherein the isolation structure is located in the substrate between the first doped region and the second doped region, and separated from the gate structure by a non-zero distance;
forming an insulating layer extending continuously from a portion of a top surface of the gate structure to a portion of a top surface of the isolation structure;
forming a field plate on the insulating layer; and
electrically connecting the field plate to the gate structure so as to make the field plate and the gate structure equipotential.

13. The method according to claim 12, wherein forming the insulating layer and forming the field plate comprise:
forming an insulating material on the substrate;
forming a field plate material on the insulating material;
patterning the field plate material to form the field plate; and
patterning the insulating material to form the insulating layer.

14. The method according to claim 13, wherein the insulating layer comprises a salicide block layer.

15. The method according to claim 14, further comprising performing a self-aligned metal silicide process, so as to form a plurality of metal silicide layers on a top surface of the first doped region, a top surface of the second doped region, a top surface of the field plate, and a top surface of a gate conductive layer of the gate structure uncovered by the insulating layer, respectively.

16. The method according to claim 12, further comprising forming an interconnect structure electrically connected to the field plate and a gate conductive layer of the gate structure.

17. The method according to claim 12, wherein a thickness of the insulating layer is greater than a thickness of a gate dielectric layer of the gate structure.

18. The method according to claim 12, wherein a width of the isolation structure covered by the insulating layer is greater than 30% to 80% of a top width of the isolation structure.

19. The method according to claim 12, wherein the insulating layer is a salicide block layer.

20. The method according to claim 12, wherein the insulating layer comprise silicon oxide.
